(19) United States
(12) Patent Application Publication
(10) Pub. No.: US 2025/0309895 A1
(43) Pub. Date: Oct. 2, 2025

(54) TOUCH SWITCH DEVICE FOR A VEHICLE AND A METHOD FOR MANUFACTURING SAME

(71) Applicants: HYUNDAI MOTOR COMPANY, Seoul (KR); KIA CORPORATION, Seoul (KR); BS TECHNICS CO.,LTD., Ansan-si (KR); ALPS ELECTRIC KOREA CO.,LTD., Gwangju (KR); NIFCO KOREA INC., Asan-si (KR); HYUNDAI MOBIS CO., LTD., Seoul (KR)

(72) Inventors: Young Ju Lee, Suwon-si (KR); Jun Geun Oh, Hwaseong-si (KR); Kang Sun Lee, Seongnam-si (KR); Kwang Pyo Cho, Gwangmyeong-si (KR); Hong Sik Chang, Hwaseong-si (KR); Seung Sik Han, Hwaseong-si (KR); Young Jai Im, Hwaseong-si (KR); Jun Sik Kim, Gwacheon-si (KR); Young Do Kim, Ansan-si (KR); Jung Sik Choi, Siheung-si (KR); Tae Kyoung Jung, Bucheon-si (KR); In Ho Park, Incheon (KR); Won Il Lee, Gwangju (KR); Dae Woo Park, Gwangju (KR); Jong Chae Lee, Asan-si (KR); Jun Hyun Park, Asan-si (KR); Jong Eun Park, Yongin-si (KR); Kwan Woo Lee, Yongin-si (KR)

(73) Assignees: HYUNDAI MOTOR COMPANY, Seoul (KR); KIA CORPORATION, Seoul (KR); BS TECHNICS CO.,LTD., Ansan-si (KR); ALPS ELECTRIC KOREA CO.,LTD., Gwangju (KR); NIFCO KOREA INC., Asan-si (KR); HYUNDAI MOBIS CO., LTD., Seoul (KR)

(21) Appl. No.: 18/815,577

(22) Filed: Aug. 26, 2024

(30) Foreign Application Priority Data
Mar. 27, 2024 (KR) 10-2024-0041926

(51) Int. Cl. H03K 17/96

(52) U.S. Cl. CPC H03K 17/962; H03K 2217/960755

(57) ABSTRACT

A touch switch device for a vehicle and a method of manufacturing the touch switch device are proposed. The touch switch device includes an external panel that is a vehicle internal material on which symbols for selecting vehicle functions are engraved. The touch switch device also includes a switch body on which a touch electrode pattern sensing a touch to the symbol as a capacitance value is plated and to which a symbol-illuminating LED is attached and which is attached to a lower portion of the external panel. The touch switch device is configured such that a touch sensing of the touch electrode pattern is performed when the symbol of the external panel is touched, so that the vehicle function corresponding to the touched symbol is operated and, at the same time, the touched symbol is illuminated by turning on the LED.

### CROSS REFERENCE TO RELATED APPLICATION

The present application claims priority to Korean Patent Application No. 10-2024-0041926, filed Mar. 27, 2024, the entire contents of which are incorporated herein for all purposes by this reference.

### TECHNICAL FIELD OF THE DISCLOSURE

The present disclosure relates to a touch switch device for a vehicle and a method for manufacturing the touch switch.

### BACKGROUND OF THE DISCLOSURE

In an interior of a vehicle, various types of switches capable of operating various electrical components, such as a button-type switch, a lever-type switch, a touch-type switch, and so on, are mounted.

In addition, various types of switches, such as a button-type switch, a lever-type switch, a touch-type switch, or the like, are mounted on a dashboard, a steering wheel, a center fascia panel, a center console, or the like that is within direct reach of a driver's hand or a passenger's hand.

In a conventional touch-type switch, the conventional touch-type switch is manufactured as a module. In the module, a touch panel, a sensor sheet, a holder, and a Printed Circuit Board (PCB) are stacked and assembled in order. On the touch panel, an actual touch is performed. A sensor sheet is stacked on a lower portion of the touch panel such that a touch to an external panel is recognized and sensed as a capacitance value. The holder is attached to a lower portion of the sensor sheet and configured to fix and support the sensor sheet. The PCB is disposed at a lower portion of the holder and configured to process a signal of the sensor sheet.

However, as described above, the conventional touch-type switch requires a large number of parts and has a complicated assembly structure, so that there is a problem that the conventional touch-type switch has limitations in applying the conventional touch-type switch as a touch-type switch for a vehicle. The subject matter described in this background section is intended to promote an understanding of the background of the disclosure and thus may include subject matter that is not already known to those of ordinary skill in the art.

### SUMMARY

The present disclosure has been made keeping in mind the above problems occurring in the related art. An objective of the present disclosure is to provide a touch switch device for a vehicle and to provide a method of manufacturing the touch switch device. The touch switch device is provided with an external panel that is a vehicle internal material on which symbols for selecting vehicle functions are engraved. The touch switch device also includes a switch body that features a touch electrode pattern, which senses a touch on the symbol by measuring a capacitance value, and has a symbol-illuminating LED (e.g., LED for illuminating the symbol). The symbol-illuminating LED is attached to the switch body. The switch body is attached to a lower portion of the external panel. The touch switch device is configured such that a touch sensing of the touch electrode pattern is performed when the symbol of the external panel is touched. In other words, touch sensing by the touch electrode pattern occurs when the symbol on the external panel is touched. Thus, the touch switch device may operate the vehicle function corresponding to the touched symbol and, at the same time, may illuminate the touched symbol by turning on the LED.

In order to achieve the objective described above, according to an aspect of the present disclosure, a touch switch device for a vehicle includes a switch body. The touch switch device also includes a plurality of first mounting grooves configured to be disposed in the switch body and configured to be formed in a predetermined arrangement. The touch switch device for the vehicle also includes a touch electrode pattern configured to be plated on an external circumferential portion of the plurality of first mounting grooves. The touch switch device also includes a conductive signal line configured to be conductively connected to the touch electrode pattern and configured to be plated on an upper surface portion of the switch body. The touch switch device also includes a first terminal plated on a bottom plate and a partition wall of the plurality of first mounting grooves of the switch body. The touch switch device also includes a power supply line configured to be plated on a lower surface portion of the switch body and configured to be conductively connected to the first terminal. The touch switch device also includes a symbol-illuminating LED attached to the first terminal and configured to be turned on. The touch switch device also includes an external panel. A plurality of symbols representing vehicle functions is formed on an upper surface portion of the external panel in the predetermined arrangement of the plurality of first mounting grooves. The switch body is attached to a lower surface portion of the external panel.

In addition, a plurality of second mounting grooves may be further formed in the switch body. An indicator symbol may be further formed on the external panel in the predetermined arrangement of the plurality of second mounting grooves.

In addition, a second terminal conductively connected to the power supply line may be further plated on a bottom surface of the second mounting grooves. An indicator LED configured to illuminate the indicator symbol may be attached to the second terminal.

The touch electrode pattern may be configured to sense a user's touch on each symbol as a capacitance value. In other words, the touch electrode pattern may be designed to detect a user's touch on each symbol by measuring the capacitance value.

In addition, the touch switch device may further include a controller configured to receive a signal sensed by the touch electrode pattern through the conductive signal line.

The controller may be configured to perform a power supply control through the power supply line after the controller receives the signal sensed by the touch electrode pattern.

Desirably, a surface of the upper surface portion of the switch body may be formed in a shape same as a surface shape of the external panel.

In addition, the symbol-illuminating LED may be attached to the partition wall of each of the first mounting grooves of the switch body, and the symbol-illuminating LED is capable of being turned on.

In addition, a light-emitting range and a luminance distribution of the symbol-illuminating LED may be adjusted according to an inclination of the partition wall of the switch body.

In order to achieve the objective described above, according to another aspect of the present disclosure, a method for manufacturing a touch switch device for a vehicle includes forming a plurality of first mounting grooves, having a predetermined arrangement, in a switch body. The method for manufacturing the touch switch device also includes plating a touch electrode pattern onto an external circumferential portion of the plurality of first mounting grooves. The method for manufacturing the touch switch device also includes forming a conductive signal line on an upper surface portion of the switch body. The method for manufacturing the touch switch device also includes connecting a power supply line to a first terminal by connecting the conductive signal line to the touch electrode pattern, the first terminal formed in the plurality of first mounting grooves, and the power supply line formed on a lower surface portion of the switch body. The method for manufacturing the touch switch device also includes attaching a symbol-illuminating LED to the first terminal. The method for manufacturing the touch switch device also includes forming a plurality of symbols representing vehicle functions on an upper surface portion of an external panel in the predetermined arrangement of the plurality of first mounting grooves. The method for manufacturing the touch switch device for the vehicle also includes attaching the switch body to a lower surface portion of the external panel.

The method for manufacturing the touch switch device also includes forming a plurality of second mounting grooves in the switch body. The method for manufacturing the touch switch device for the vehicle also includes forming an indicator symbol on the external panel in the predetermined arrangement of the plurality of second mounting grooves when forming the external panel.

The method for manufacturing the touch switch device also includes attaching an indicator LED illuminating the indicator symbol by plating a second terminal, conductively connected to the power supply line, on a bottom surface of the second mounting grooves.

In addition, the method for manufacturing the touch switch device for the vehicle may further include transmitting a signal by connecting the conductive signal line and the power supply line to a controller.

The method for manufacturing the touch switch device for the vehicle also includes performing, by the controller, a power supply control through the power supply line after the controller receives a signal sensed by the touch electrode pattern.

The method for manufacturing the touch switch device for the vehicle also includes adjusting a light-emitting range and a luminance distribution of the symbol-illuminating LED attached to a partition wall of the plurality of first mounting grooves by adjusting an inclination of the partition wall.

According to the above configurations, the present disclosure has the following effects.

First, the touch switch device for the vehicle is configured only with the external panel that is the vehicle interior material on which the plurality of symbols for selecting the vehicle functions is engraved. The touch switch device for the vehicle includes the switch body on which the touch electrode pattern sensing a touch as a capacitance value is plated and to which the LED is attached. Thus, the number of parts, the number of assembly processes, and the manufacturing cost may be reduced compared to that of a conventional touch switch.

Second, since the switch body is manufactured in a three-dimensional shape that is the same as the surface shape of the external panel, a touch to the symbol of the external panel may be easily recognized and sensed in the touch electrode pattern of the switch body.

Third, by adjusting the angle of the partition wall to which the symbol-illuminating LED of the switch body is mounted, the light-emitting range and the concentrated luminance distribution of the symbol-illuminating LED may be variously set.

### BRIEF DESCRIPTION OF THE DRAWINGS

The above and other objectives, features, and other advantages of the present disclosure should be more clearly understood from the following detailed description when taken in conjunction with the accompanying drawings, in which:

FIG. 1 is a plan view illustrating a switch body of a touch switch device for a vehicle according to an embodiment of the present disclosure;

FIG. 2 is a bottom view illustrating the switch body of the touch switch device for the vehicle according to an embodiment of the present disclosure;

FIG. 3 is an enlarged perspective view illustrating a main part in a state in which a touch electrode pattern is plated on the switch body of the touch switch device for the vehicle according to an embodiment of the present disclosure;

FIG. 4 is a schematic view illustrating a state in which an external panel, which is a type of an interior material for the vehicle, is attached to the switch body of the touch switch device according to an embodiment of the present disclosure;

FIG. 5 is a cross-sectional view illustrating the state in which the external panel, which is the type of the interior material for the vehicle, is attached to the switch body of the touch switch device according to an embodiment of the present disclosure;

FIG. 6 is an enlarged cross-sectional view illustrating the main part in a state in which an LED is attached to a partition wall portion of the switch body of the touch switch device according to an embodiment of the present disclosure; and

FIGS. 7A, 7B, and 7C are cross-sectional views illustrating an example in which a light-emitting range and a concentrated luminance distribution of the LED are variously set by performing an angle adjustment for the partition wall portion of the switch body of the touch switch device for the vehicle according to the present disclosure.

### DETAILED DESCRIPTION

Specific structures and functions stated in the embodiment of the present disclosure are intended to illustrate an embodiment according to the spirit of the present disclosure, and embodiments according to the spirit of the present disclosure can be achieved in various ways. In addition, the present disclosure should not be construed as being limited to the following embodiments and should be construed as including all changes, equivalents, and replacements included in the spirit and scope of the present disclosure.

In the present disclosure, terms including “first” and/or “second” may be used to describe various components, but the components are not limited to the terms. The terms are used to distinguish one component from another component, and for instance, a first component may be referred to as a second component. Similarly, a second component may be referred to as a first component without departing from the scope according to the spirit of the present disclosure.

In the present disclosure, when a component is referred to as being “connected” or “coupled” to another component, it should be understood that the component may be directly connected or coupled to the other component, but other components may exist therebetween. On the other hand, when a component is referred to as being “directly connected” or “directly contacted” to another component, it should be understood that there is no other component therebetween. Expressions for describing relationships between components, i.e., “between”, “directly between”, “adjacent to”, and “directly adjacent to” should be construed in the same way as stated above.

Like components are denoted by like reference numerals throughout the present disclosure. Terms used in the present disclosure are used to describe embodiments of the present disclosure and are not intended to limit the scope of the present disclosure. In the present disclosure, the terms of a singular form may include plural forms unless otherwise specified. It should be further understood that the terms “comprise”, “include”, “have”, etc., when used in this present disclosure, specify the presence of stated components, steps, operations, and/or elements but do not preclude the presence or addition of one or more other components, steps, operations, and/or elements thereof. When a controller, module, component, device, element, or the like of the present disclosure is described as having a purpose or performing an operation, function, or the like, the controller, module, component, device, element, or the like should be considered herein as being “configured to” meet that purpose or to perform that operation or function. Each controller, module, component, device, element, and the like may separately embody or be included with a processor and a memory, such as a non-transitory computer readable media, as part of the apparatus.

Hereinafter, an embodiment of the present disclosure is described with reference to accompanying drawings.

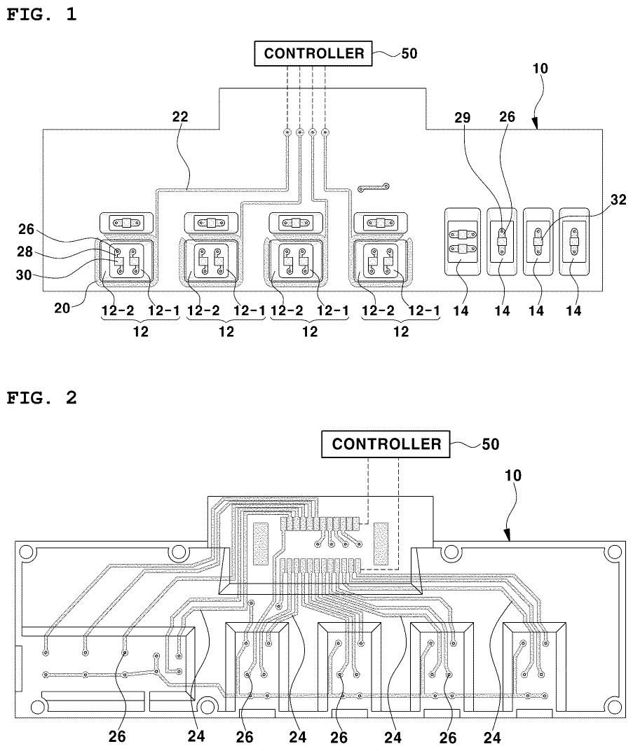

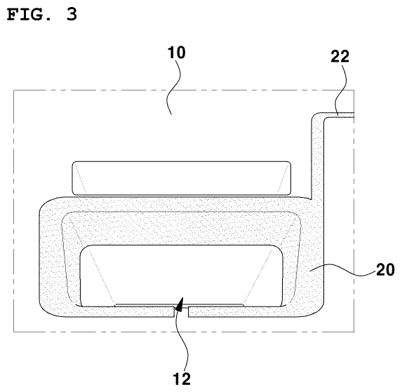

FIG. 1 is a plan view illustrating a switch body of a touch switch device for a vehicle according to the present disclosure. FIG. 2 is a bottom view illustrating the switch body of the touch switch device for the vehicle according to the present disclosure. FIG. 3 is an enlarged perspective view illustrating a main part in a state in which a touch electrode pattern is plated on the switch body of the touch switch device for the vehicle according to the present disclosure.

First, a switch body 10 is formed and manufactured in a desired shape by using an insulating plastic material.

According to an embodiment of the present disclosure, as illustrated in FIG. 1 and FIG. 3, the switch body 10 may be formed in a rectangular plate body structure in which a plurality of first mounting grooves 12 where symbol-illuminating LEDs are mounted. A plurality of second mounting grooves 14 where indicator LEDs are mounted are formed in a predetermined arrangement.

Next, a circuit region for plating a touch electrode pattern and a conductive signal line 22 over an upper surface portion of 20 the switch body 10 and over the first mounting groove 12 is formed by using a laser circuit processing method. A circuit region for plating a power supply line 24 over a lower surface portion of the switch body 10 is formed by using the laser circuit processing method.

Then, a process of filling and plating the touch electrode pattern 20 and the conductive signal line 22 by performing a plating process on the circuit region formed over the upper surface portion of the switch body 10 and over the first mounting groove 12 is performed. A process of filling and plating the power supply line 24 by performing a plating process on the circuit region formed over the lower surface portion of the switch body 10 is performed.

In addition, by performing an electroless plating process, the touch electrode pattern 20, the conductive signal line 22, and the power supply line 24 that are capable of being made of a copper material, a nickel material, or an aluminum material may be plated on the circuit regions formed by performing the laser circuit processing process over the upper surface portion and the lower surface portion of the switch body 10.

As illustrated in FIG. 3, the touch electrode pattern 20 may be formed over each external circumferential portion in four directions of the plurality of first mounting grooves 12 formed in the switch body 10. The conductive signal line 22 may be formed such that the conductive signal line 22 is conductively connected to the touch electrode pattern 20 and is formed in a predetermined arrangement over the upper surface portion of the switch body 10. Therefore, when the touch electrode pattern 20 senses a touch by a user's finger and so on as a capacitance value, the sensed signal may be transmitted to a controller 50 through the conductive signal line 22.

In addition, as illustrated in FIG. 2, the power supply line 24 is formed in a predetermined pattern on the lower surface portion of the switch body 10.

Accordingly, a power may be supplied to the power supply line 24 by a power supply application signal of the controller 50.

In the plating process, a first terminal 28 for attaching each symbol-illuminating LED to each bottom plate 12-1 of the first mounting grooves 12 of the switch body 10 is further plated. A second terminal 29 for attaching each indicator LED to each bottom surface of the second mounting grooves 14 is further plated.

Meanwhile, by each conductive via hole 26 formed in the first mounting grooves 12 and the second mounting grooves 14, the power supply line 24 and each of the terminals 28 and 29 may be electrically connected to each other.

Therefore, by the power supply application signal of the controller 50, the power may be supplied to each of the terminals 28 and 29 through the power supply line 24 and the conductive via hole 26.

Subsequently, each symbol-illuminating LED 30 is attached to each first terminal 28 plated on the bottom plate 12-1 of each first mounting groove 12 of the switch body 10 such that the LED 30 is capable of being turned on. Each indicator LED 32 is attached to each second terminal 29 plated on the bottom surface of each second mounting groove 14 such that the LED 32 is capable of being turned on.

Therefore, by the power supply application signal of the controller 50, the power is supplied to each of the terminals 28 and 29 through the power supply line 24 and the conductive via hole 26, so that each symbol-illuminating LED 30 and each indicator LED 32 are capable of being turned on.

Next, the switch body 10 is attached to an external panel 40 that is an interior material of the vehicle (for example, a center garnish of a cockpit module positioned within reach of a driver's hand or a passenger's hand). The, the switch body 10 is assembled.

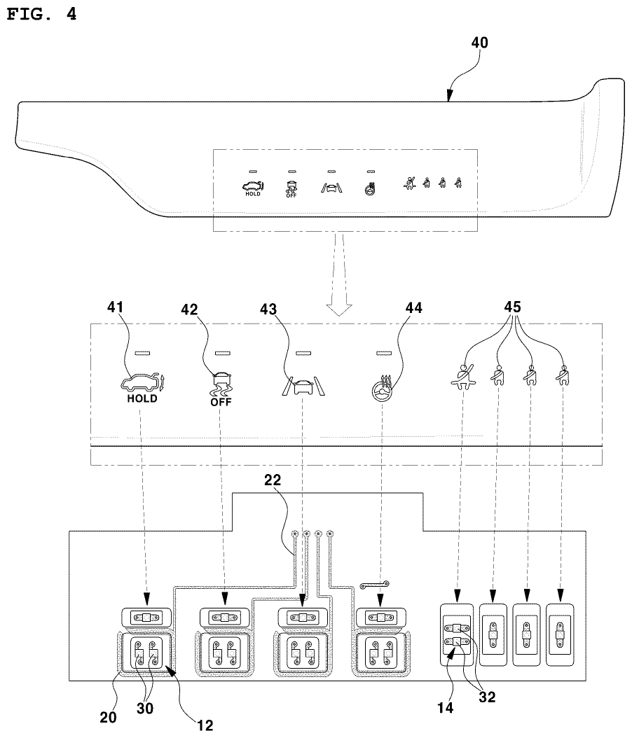

Referring to FIG. 4, a first symbol 41, a second symbol 42, a third symbol 43, and a fourth symbol 44 indicating respective vehicle functions are formed on an upper surface portion of the external panel 40. The external panel 40 has a structure in which an indicator symbol 45 is formed.

For example, the first symbol 41 may indicate a function of opening a trunk lid or a tailgate among the vehicle functions. The second symbol 42 may indicate an Electronic Stability Control (ESC) function among the vehicle functions. The third symbol 43 may indicate a lane keeping assistance system among the vehicle functions. The fourth symbol 44 may indicate a steering wheel heating wire function. The indicator symbol 45 may be a warning light for not wearing a seat belt for each seat.

At this time, the plurality of symbols 41, 42, 43, and 44 is formed in the same arrangement and the same interval as the plurality of first mounting grooves 12 formed in the switch body 10.

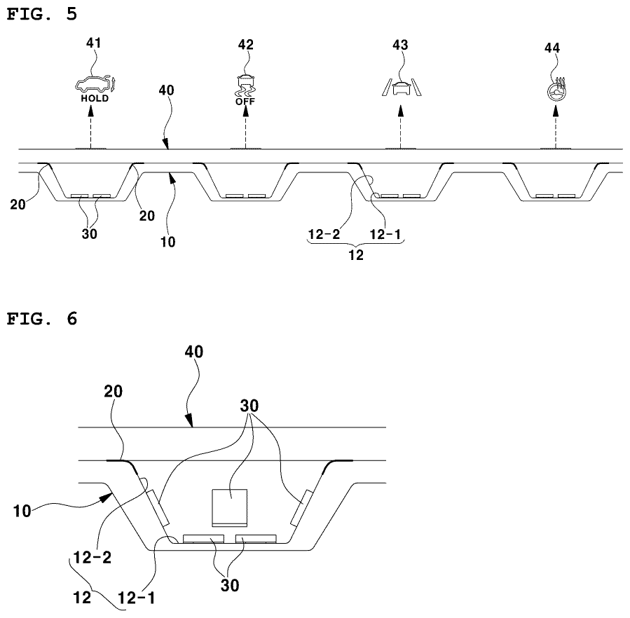

As illustrated in FIG. 5, when the switch body 10 is attached and assembled to a bottom surface portion of the external panel 40 provided in this manner, the first symbols 41 to the fourth symbols 44 are respectively positioned on the plurality of first mounting grooves 12 formed in the switch body 10, and the indicator symbol 45 is positioned on each of the second mounting grooves 14.

In one embodiment, a surface of the upper surface portion of the switch body 10, except for each of the mounting grooves 12 and 14, is formed in a three-dimensional shape equal to a surface shape of the external panel 40 that is the interior material of the vehicle. Therefore, the switch body 10 is capable of being easily in close contact with and being attached to the bottom portion of the external panel 40 without being separated, so that the user's touch to each of the symbols 41, 42, 43, and 44 of the external panel 40 may be easily recognized and sensed by the touch electrode pattern 20 of the switch body 10.

As such, the touch switch device for the vehicle is configured only with the external panel 40 that is the vehicle interior material in which the plurality of symbols for selecting the vehicle functions is engraved. The touch switch device for the vehicle is also configured with the switch body 10 on which the touch electrode pattern 20 that senses a touch as a capacitance value is plated and to which the symbol-illuminating LED 30 and so on are attached. Thus, the number of parts, the number of assembly processes, and the manufacturing cost may be reduced compared to that of a conventional touch switch.

Here, an operation flow of the touch switch device for the vehicle of the present disclosure configured as described above is as follows.

First, the user touches at least one of the first symbol 41, the second symbol 42, the third symbol 43, and the fourth symbol 44 of the outer panel 40 that is the interior material of the vehicle with a finger or the like.

For example, the user may touch the first symbol 41 to use the function of opening the trunk lid or the tailgate among the vehicle functions, may touch the second symbol 42 to turn off the ESC, may touch the third symbol 43 to use the lane keeping assist system, or may touch the fourth symbol 44 to use the steering wheel heating wire.

Therefore, when the user touches at least one of the first symbol 41, the second symbol 42, the third symbol 43, or the fourth symbol 44 of the external panel 40, the touch is sensed as a capacitance value in the touch electrode pattern 20 plated on the switch body 10, and the sensed signal is transmitted to the controller 50 through the conductive signal line 22.

Subsequently, the vehicle function corresponding to the symbol touched may be performed by the control of the controller 50.

At the same time, as the power is supplied to the terminal 28 through the power supply line 24 and the conductive via hole 26 by the power application signal of the controller 50, the symbol-illuminating LED 30 is lighted on.

Therefore, since the symbol-illuminating LED 30 for illuminating the touched symbol is lighted on, the touched symbol is capable of being illuminated, and the user may easily and visually recognize that the vehicle function of the touched symbol is activated.

For example, when the user touches the first symbol 41 of the external panel 40, the function of opening the trunk lid or the tailgate, which is the function of the first symbol 41 that is touched, is performed by the control of the controller 50 and the symbol-illuminating LED 30 for illuminating the first symbol 41 is lighted on, and the first symbol 41 may be illuminated. Thus, the user may easily and visually recognize that the function of opening the trunk lid or the tailgate, which is the vehicle function of the first symbol 41, is performed.

At this time, when the user or other passengers are not wearing seat belts, the power is supplied to the terminal 29 through the power supply line 24 and the conductive via hole 26 by the power supply application signal of the controller 50. Thus, the indicator LED 32 may be lighted on, and the indicator symbol 45 is illuminated by the light illumination of the indicator LED 32.

Accordingly, the driver and others may visually recognize that the indicator symbol 45, which is the warning light for not wearing the seat belt for each seat, is illuminated. They may instruct to wear the seat belt.

In the plating process, in addition to the bottom plate 12-1 of each of the first mounting grooves 12 of the switch body 10, the first terminal 28 for attaching the symbol-illuminating LED to a partition wall 12-2 in four directions of the first mounting groove 12 may be further plated. Furthermore, as illustrated in FIG. 6, the symbol-illuminating LED 30 may be further attached to the first terminal 28 plated on the partition wall 12-2 so as to adjust a light-emitting range (an illumination range) and a luminance distribution of the symbol-illuminating LED.

When the symbol-illuminating LED 30 is attached to the first terminal 28 that is plated on the partition wall 12-2 of the first mounting groove 12, the symbol-illuminating LED 30 may not be attached to the bottom plate 12-1 of the first mounting groove 12.

In addition, in order to adjust the light-emitting range (the illumination range) and the luminance distribution of the LED for illuminating the symbol, an inclination of the partition wall 12-2 may be adjusted in various forms when the switch body 10 is formed and manufactured.

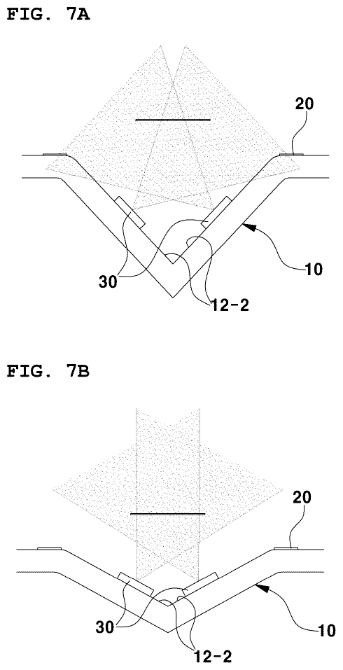

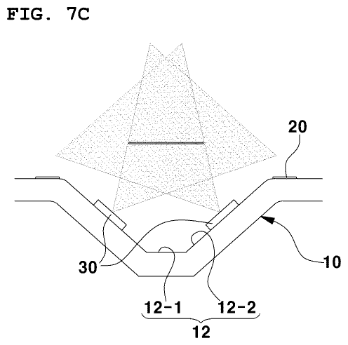

For example, the partition wall 12-2 of the switch body 10 may be formed in a “V” shape having a maximum inclination as illustrated in FIG. 7A. Alternatively, the partition wall 12-2 of the switch body 10 may be formed in a “V” shape having a minimum inclination as illustrated in FIG. 7B. Alternatively, the partition wall 12-2 of the switch body 10 may be formed in a “V” shape having an intermediate inclination between the maximum inclination and the minimum inclination as illustrated in FIG. 7C. Thus, the light-emitting range and the luminance distribution of the LED 30 for illuminating the symbol may be easily adjusted.

As such, by adjusting an angle of the partition wall 12-2 of the switch body 10 to which the symbol-illuminating LED 30 is attached, the light-emitting range and the luminance distribution of the symbol-illuminating LED 30 is capable of being variously set.

Although an embodiment of the present disclosure has been described in detail, the scope of the prevent disclosure is not limited to the embodiment, and various modifications and improvements devised by those having ordinary skill in the art using the fundamental concept of the present disclosure, which is defined by the appended claims, may further fall within the scope of the present disclosure.

What is claimed is:

1. A touch switch device for a vehicle, the touch switch device comprising:
a switch body,
a plurality of first mounting grooves configured to be disposed in the switch body and configured to be formed in a predetermined arrangement;
a touch electrode pattern configured to be plated on an external circumferential portion of the plurality of first mounting grooves;
a conductive signal line configured to be conductively connected to the touch electrode pattern and configured to be plated on an upper surface portion of the switch body;
a first terminal plated on a bottom plate and a partition wall of the plurality of first mounting grooves of the switch body;
a power supply line configured to be plated on a lower surface portion of the switch body and configured to be conductively connected to the first terminal;
a symbol-illuminating LED attached to the first terminal and configured to be turned on; and
an external panel,
wherein a plurality of symbols representing vehicle functions is formed on an upper surface portion of the external panel in the predetermined arrangement of the plurality of first mounting grooves, and
wherein the switch body is attached to a lower surface portion of the external panel.

2. The touch switch device of claim 1, further comprising:
a plurality of second mounting grooves disposed in the switch body; and
an indicator symbol formed on the external panel in the predetermined arrangement of the plurality of second mounting grooves.

3. The touch switch device of claim 2, further comprising:
a second terminal configured to be conductively connected to the power supply line and plated on a bottom surface of the second mounting grooves; and
an indicator LED configured to illuminate the indicator symbol and attached to the second terminal.

4. The touch switch device of claim 1, wherein the touch electrode pattern is configured to sense a touch of a user to each symbol as a capacitance value.

5. The touch switch device of claim 4, further comprising:
a controller configured to receive a signal sensed by the touch electrode pattern through the conductive signal line.

6. The touch switch device of claim 5, wherein the controller is configured to perform a power supply control through the power supply line after the controller receives the signal sensed by the touch electrode pattern.

7. The touch switch device of claim 1, wherein a surface of the upper surface portion of the switch body is formed in a shape same as a surface shape of the external panel.

8. The touch switch device of claim 1, wherein the symbol-illuminating LED is attached to the partition wall of each of the plurality of first mounting grooves of the switch body and is configured to be turned on.

9. The touch switch device of claim 8, wherein a light-emitting range and a luminance distribution of the symbol-illuminating LED are adjusted according to an inclination of the partition wall of the switch body.

10. A method for manufacturing a touch switch device for a vehicle, the method comprising:
forming a plurality of first mounting grooves, having a predetermined arrangement, in a switch body;
plating a touch electrode pattern formed on an external circumferential portion of the plurality of first mounting grooves;
forming a conductive signal line on an upper surface portion of the switch body;
connecting a power supply line to a first terminal by connecting the conductive signal line to the touch electrode pattern, the first terminal formed in the plurality of first mounting grooves, and the power supply line formed on a lower surface portion of the switch body;
attaching a symbol-illuminating LED to the first terminal;
forming a plurality of symbols representing vehicle functions on an upper surface portion of an external panel in the predetermined arrangement of the plurality of first mounting grooves; and
attaching the switch body to a lower surface portion of the external panel.

11. The method of claim 10, further comprising:
forming a plurality of second mounting grooves in the switch body; and
forming an indicator symbol on the external panel in the predetermined arrangement of the plurality of second mounting grooves when forming the external panel.

12. The method of claim 11, further comprising:
attaching an indicator LED illuminating the indicator symbol by plating a second terminal, conductively connected to the power supply line, on a bottom surface of the second mounting grooves.

13. The method of claim 10, further comprising:
transmitting a signal by connecting the conductive signal line and the power supply line to a controller.

14. The method of claim 13, further comprising:
performing, by the controller, a power supply control through the power supply line after the controller receives a signal sensed by the touch electrode pattern.

15. The method of claim 10, further comprising:
adjusting a light-emitting range and a luminance distribution of the symbol-illuminating LED attached to a partition wall of the plurality of first mounting grooves by adjusting an inclination of the partition wall.
